(19) United States
(12) Patent Application Publication
(10) Pub. No.: US 2023/0290605 A1
(43) Pub. Date: Sep. 14, 2023

(54) PHOTOELECTRIC SURFACE ELECTRON SOURCE

(71) Applicants: HAMAMATSU PHOTONICS K.K., Hamamatsu-shi, Shizuoka (JP); NuFlare Technology, Inc., Yokohama-shi, Kanagawa (JP)

(72) Inventors: Tomohiko HIRANO, Hamamatsu-shi, Shizuoka (JP); Hiroyuki TAKETOMI, Hamamatsu-shi, Shizuoka (JP); Motohiro SUYAMA, Hamamatsu-shi, Shizuoka (JP); Wataru MATSUDAIRA, Hamamatsu-shi, Shizuoka (JP); Akihiro KAGEYAMA, Hamamatsu-shi, Shizuoka (JP); Kota IWASAKI, Yokohama-shi, Kanagawa (JP); Taku YAMADA, Yokohama-shi, Kanagawa (JP)

(73) Assignees: HAMAMATSU PHOTONICS K.K., Hamamatsu-shi, Shizuoka (JP); NuFlare Technology, Inc., Yokohama-shi, Kanagawa (JP)

(21) Appl. No.: 18/020,989

(22) PCT Filed: Jun. 9, 2021
(86) PCT No.: PCT/JP2021/021943

§ 371 Date: Feb. 13, 2023

(30) Foreign Application Priority Data
Aug. 21, 2020 (JP) 2020-140149

(51) Int. Cl. H01J 37/06; H01J 37/10

(52) U.S. Cl. CPC H01J 37/06; H01J 37/10; H01J 2237/026

(57) ABSTRACT

A photoelectric surface electron source includes a glass substrate configured to receive laser light incident from a substrate back surface to emit the laser light from a substrate main surface, a photoelectric surface provided on the substrate main surface and configured to receive the laser light and emit a photoelectron, a lens array disposed on the substrate back surface and including a plurality of microlenses for condensing the laser light toward the photoelectric surface, and a light shielding portion provided on the glass substrate. The light shielding portion has a back surface-side light shielding layer provided on a back surface-side light shielding surface interposed between the plurality of microlenses on the substrate back surface, and a main surface-side light shielding layer provided on a main surface-side light shielding surface.

### TECHNICAL FIELD

The present invention relates to a photoelectric surface electron source.

### BACKGROUND ART

Conventionally, an electron source has been used. The electron source emits a photoelectron in response to externally incident light. For example, Patent Literature 1 discloses a charged particle beam column device that generates a plurality of electron beams. The charged particle beam column device emits a photoelectron in response to externally incident light. The charged particle beam column device includes a beam source and a lens. The beam source generates a plurality of charged particle beams. The lens demagnifies the charged particle beams.

### CITATION LIST

### Patent Literature

Patent Literature 1: Japanese Unexamined Patent Publication No. 2003-511855

### SUMMARY OF INVENTION

### Technical Problem

For example, the electron source is used in an electron beam lithography device. The electron beam lithography device is constantly required to improve productivity. Examples of a scheme of improving productivity include outputting a plurality of electron beams. Examples of a device for outputting a plurality of electron beams include the charged particle beam column device of Patent Literature 1.

When the electron source is used in the electron beam lithography device, etc., it is important to have the ability to accurately apply an electron beam having desired beam characteristics to a desired position. In other words, there is a demand for a photoelectric surface electron source capable of accurately applying a plurality of electron beams having desired beam characteristics to a plurality of desired positions.

The invention provides a photoelectric surface electron source capable of accurately applying a plurality of electron beams.

### Solution to Problem

A photoelectric surface electron source which is an aspect of the invention includes a substrate configured to receive light incident from a substrate back surface to emit the light from a substrate main surface on an opposite side from the substrate back surface, a photoelectric surface provided on the substrate main surface and configured to receive the light and emit a photoelectron, a lens part disposed on a side of the light-receiving surface and including a plurality of lenses for condensing the light toward the photoelectric surface, and a light shielding portion provided on the substrate. The light shielding portion has at least one of a first light shielding layer provided in a first region interposed between the plurality of lenses on the substrate back surface and a second light shielding layer provided in a second region facing the first region on the substrate main surface.

The photoelectric surface electron source includes the plurality of lenses. Therefore, a plurality of electron beams can be emitted by irradiation with light. The photoelectric surface electron source includes the light shielding portion. Further, the light shielding portion has at least one of the first light shielding layer provided on the substrate back surface and the second light shielding layer provided on the substrate main surface. The first light shielding layer can limit light incident on the substrate to light passing through the lens part. The second light shielding layer can limit light irradiated to the photoelectric surface to light condensed by the lens part. As a result, incidence of light not passing through the lens part on the photoelectric surface is suppressed. Therefore, light condensed by the lens part can be reliably made incident on a predetermined region of the photoelectric surface. Therefore, an electron beam can be applied with high accuracy.

In an aspect, the light shielding portion may exclusively have the first light shielding layer. According to this configuration, a region in which light is received on the substrate back surface can be reliably limited only to the lens part.

In an aspect, the light shielding portion may exclusively have the second light shielding layer. According to this configuration, only light passing through the lens part on the substrate main surface can be irradiated to the photoelectric surface.

In an aspect, the light shielding portion may have the first light shielding layer and the second light shielding layer. According to this configuration, the region in which light is received on the substrate back surface can be reliably limited only to the lens part. Only light passing through the lens part on the substrate main surface can be irradiated to the photoelectric surface.

In an aspect, the second light shielding layer may have light passing openings allowing the light condensed by the lenses to pass therethrough. An area of the light passing openings is smaller than an area of the lenses. According to this configuration, only light condensed by the lens part on the substrate main surface can be reliably irradiated to the photoelectric surface.

In an aspect, the second light shielding layer may have a light passing opening allowing the light condensed by the lenses to pass therethrough and may have directly formed on the substrate main surface. The photoelectric surface may include a first photoelectric surface portion formed on the substrate main surface exposed from the light passing opening, and a second photoelectric surface portion formed on the second light shielding layer. According to this configuration, even when the photoelectric surface is formed on a front surface on the second light shielding layer, the light condensed by the lens part can be incident only on the first photoelectric surface portion.

In an aspect, the substrate main surface may include a first main surface portion and a second main surface portion recessed from the first main surface portion. The second light shielding layer may be provided on the second main surface portion. According to this configuration, the second light shielding layer can be reliably disposed in a desired region on the substrate main surface.

In an aspect, the second light shielding layer may be flush with the first main surface portion. According to this configuration, the photoelectric surface can be formed on the first main surface portion. Further, the photoelectric surface can be formed on the second light shielding layer which is flush with the first main surface portion. As a result, a surface of the photoelectric surface can be flattened. Therefore, it is possible to suppress formation of an electrostatic lens that disturbs a trajectory of an electron. As a result, a desired electron trajectory can be realized, and thus an electron beam can be applied with high accuracy.

A photoelectric surface electron source of an aspect may further include a potential supply portion electrically connected to the first light shielding layer and used to set the first light shielding layer to a desired potential. According to this configuration, charging of the first light shielding layer can be suppressed.

### Advantageous Effects of Invention

The invention provides a photoelectric surface electron source capable of accurately applying a plurality of electron beams.

### BRIEF DESCRIPTION OF DRAWINGS

FIG. 1 is an exploded perspective view of a photoelectric surface electron source of an embodiment.

FIG. 2 is a plan view illustrating a back surface of an extraction electrode.

FIG. 3 is a cross-sectional view illustrating an enlarged main part of the photoelectric surface electron source.

FIG. 4 is an enlarged view of a glass substrate illustrated in FIG. 3.

FIG. 5 is a perspective view illustrating a main surface side of the glass substrate.

FIG. 6 is an enlarged cross-sectional view of a glass substrate included in a photoelectric surface electron source of a first modified example.

FIG. 7 is an enlarged cross-sectional view of a glass substrate included in a photoelectric surface electron source of a second modified example.

FIG. 8 is an enlarged cross-sectional view of a glass substrate included in a photoelectric surface electron source of a third modified example.

FIG. 9 is an enlarged cross-sectional view of a glass substrate included in a photoelectric surface electron source of a fourth modified example.

### DESCRIPTION OF EMBODIMENTS

Hereinafter, embodiments for carrying out the invention will be described in detail with reference to the accompanying drawings. In the description of the drawings, the same components are denoted by the same reference numerals, and overlapping descriptions are omitted. The drawings are simplified to facilitate understanding of content of the invention. A size, the number, etc. of each part may not match those of an actual configuration.

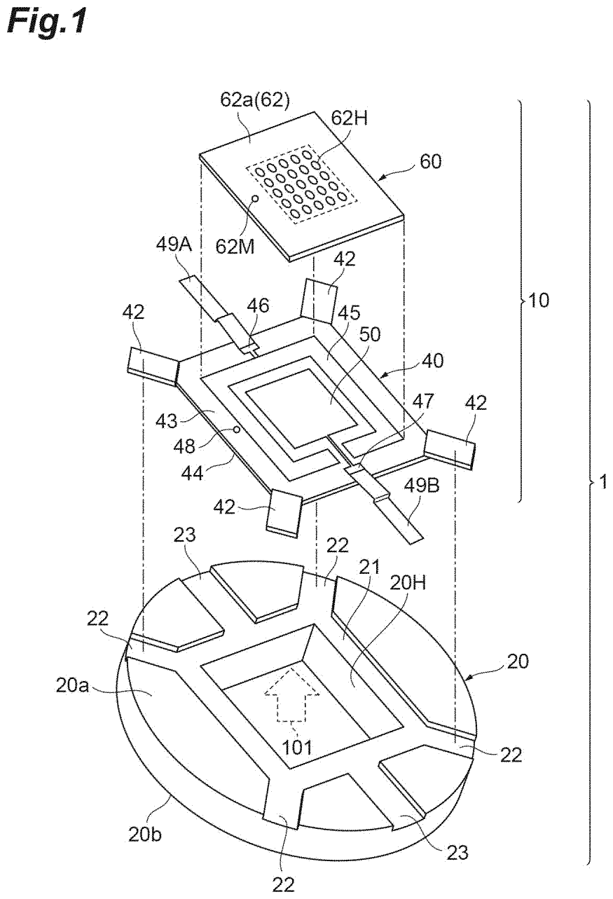

A photoelectric surface electron source 1 illustrated in FIG. 1 is a multi-beam photoelectric surface electron source capable of generating a plurality of electron beams. The photoelectric surface electron source 1, which is a high-precision multi-beam electron source, has high electron utilization efficiency and uniform electron beam characteristics. For example, the photoelectric surface electron source 1 generates a plurality of electron beams as a result of receiving laser light 101, a wavelength of which is in an ultraviolet region. The photoelectric surface electron source 1 has a photoelectric surface electron source unit 10 and a base 20 as main components.

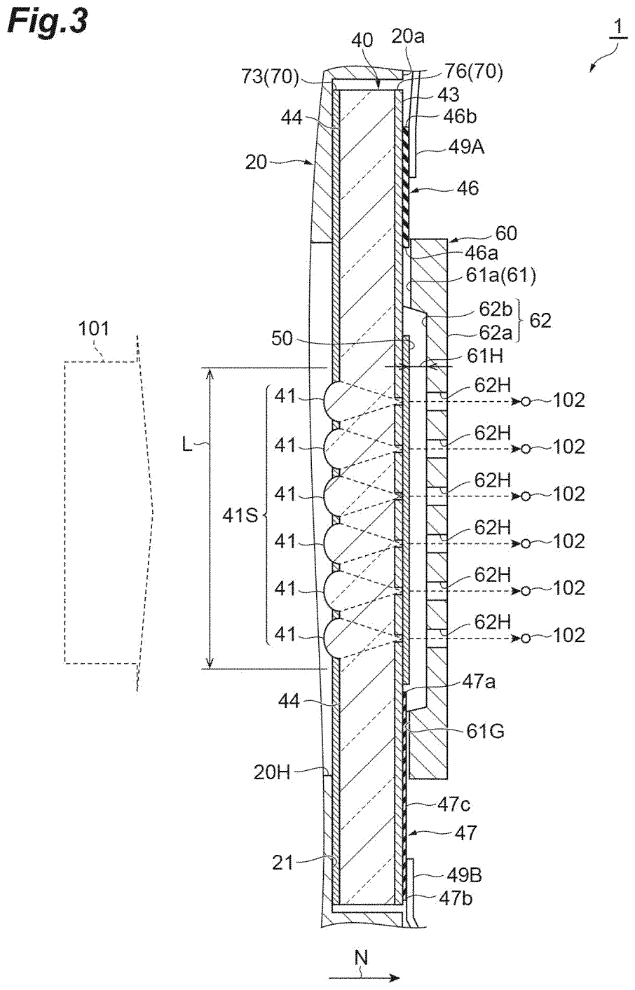

The photoelectric surface electron source unit 10 has a glass substrate 40, a photoelectric surface 50 and an extraction electrode 60. The glass substrate 40 includes a lens array 41S (lens part) provided with a plurality of microlenses 41 (lenses; see FIG. 3). The glass substrate 40 is a rectangular plate member in a plan view in a direction facing a substrate main surface 43 described later. A material of the glass substrate 40 has a property of transmitting laser light 101 irradiated to the photoelectric surface 50. For example, the material of the glass substrate 40 is quartz glass, calcium fluoride, magnesium fluoride, or sapphire.

The glass substrate 40 is disposed on the base 20. The glass substrate 40 is fixed to the base 20 by a fixing member 42. The glass substrate 40 has the substrate main surface 43 and a substrate back surface 44. The glass substrate 40 has the plurality of microlenses 41 (see FIG. 3), an electrode junction portion 45, an extraction power supply portion 46, a photoelectric surface power supply portion 47, a back surface-side light shielding layer 73 (see FIG. 3), and a main surface-side light shielding layer 76 (see FIG. 3). As illustrated in FIG. 3, the lens array region L is provided with the plurality of microlenses 41. The lens array region L is provided on the substrate back surface 44. The plurality of microlenses 41 may be provided separately from the glass substrate 40. The plurality of microlenses 41 may be separated from the glass substrate 40.

As illustrated in FIG. 1, the electrode junction portion 45, the extraction power supply portion 46, and the photoelectric surface power supply portion 47 are provided on the substrate main surface 43. The substrate main surface 43 or the substrate back surface 44 is provided with a positioning mark 48. The mark 48 is used for a positioning operation when the extraction electrode 60 is bonded to the glass substrate 40. The mark 48 is provided near the outside of the electrode junction portion 45.

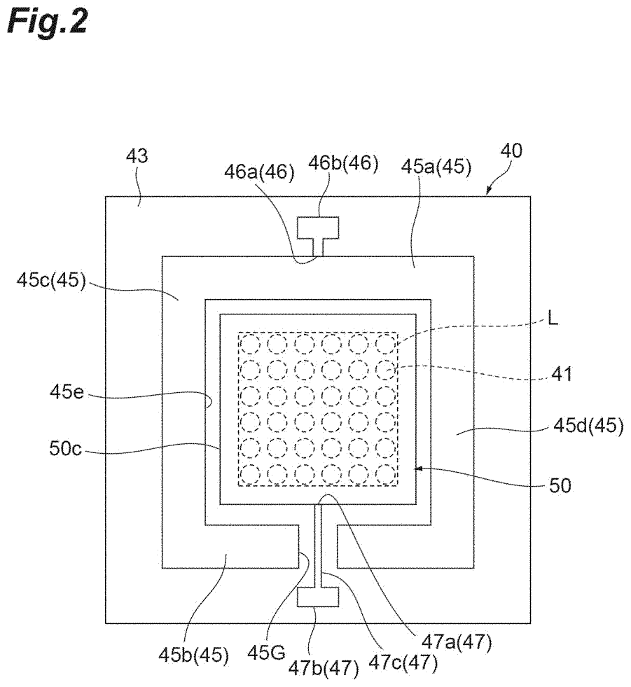

The electrode junction portion 45 fixes the extraction electrode 60 to the glass substrate 40. The electrode junction portion 45 applies a voltage given from the extraction power supply portion 46 to the extraction electrode 60. The electrode junction portion 45 is a power supply pattern provided on the substrate main surface 43 of the glass substrate 40, which is an insulator. As illustrated in FIG. 2, the electrode junction portion 45 surrounds the lens array region L in the plan view in the direction facing the substrate main surface 43 of the glass substrate 40. The lens array region L is provided with the plurality of microlenses 41. The electrode junction portion 45 has a frame shape in the plan view in the direction facing the substrate main surface 43 of the glass substrate 40. The electrode junction portion 45 includes portions 45a, 45b, 45c, and 45d. The portions 45a, 45b, 45c, and 45d are included in respective sides of the electrode junction portion 45. The portion 45b includes an opening portion 45G. The substrate main surface 43 is exposed from the opening portion 45G. A part of the photoelectric surface power supply portion 47 is disposed in the opening portion 45G.

The extraction power supply portion 46 applies a predetermined voltage to the extraction electrode 60. The extraction power supply portion 46 is provided outside the electrode junction portion 45. The extraction power supply portion 46 has an end portion 46a and an end portion 46b. The end portion 46a is connected to the electrode junction portion 45. The end portion 46b is an electrode pad. The end portion 46a is connected to the portion 45a of the electrode junction portion 45. The portion 45a faces the portion 45b provided with the opening portion 45G. A conductive fastener 49A (see FIG. 1) is electrically connected to the end portion 46b.

The photoelectric surface power supply portion 47 applies a predetermined voltage to the photoelectric surface 50. The photoelectric surface power supply portion 47 has an end portion 47a, an end portion 47b, and a wiring portion 47c. The end portion 47a is provided in a region where the photoelectric surface 50 is disposed. The end portion 47b is provided outside the electrode junction portion 45. The wiring portion 47c connects the end portion 47a to the end portion 47b. The photoelectric surface power supply portion 47 extends from the region where the photoelectric surface 50 is disposed to the outside of the electrode junction portion 45. A portion between one end portion 47a and the other end portion 47b is separated from the electrode junction portion 45. The wiring portion 47c, which is a portion between the one end portion 47a and the other end portion 47b, passes through the opening portion 45G of the electrode junction portion 45. The photoelectric surface 50 is electrically connected to the end portion 47a. The end portion 47b is an electrode pad. A conductive fastener 49B (see FIG. 1) is electrically connected to the end portion 47b.

The photoelectric surface 50 is made of platinum (Pt). The photoelectric surface 50 is rectangular in the plan view in the direction facing the substrate main surface 43 of the glass substrate 40. The photoelectric surface 50 is provided substantially in a center of the substrate main surface 43. The photoelectric surface 50 overlaps the lens array region L in the plan view in the direction facing the substrate main surface 43 of the glass substrate 40. The plurality of microlenses 41 is provided in the lens array region L. The photoelectric surface 50 is provided in a region surrounded by the electrode junction portion 45. The photoelectric surface 50 is separated from the electrode junction portion 45. The photoelectric surface 50 is electrically insulated from the electrode junction portion 45. The substrate main surface 43 is exposed from a region between the photoelectric surface 50 and the electrode junction portion 45.

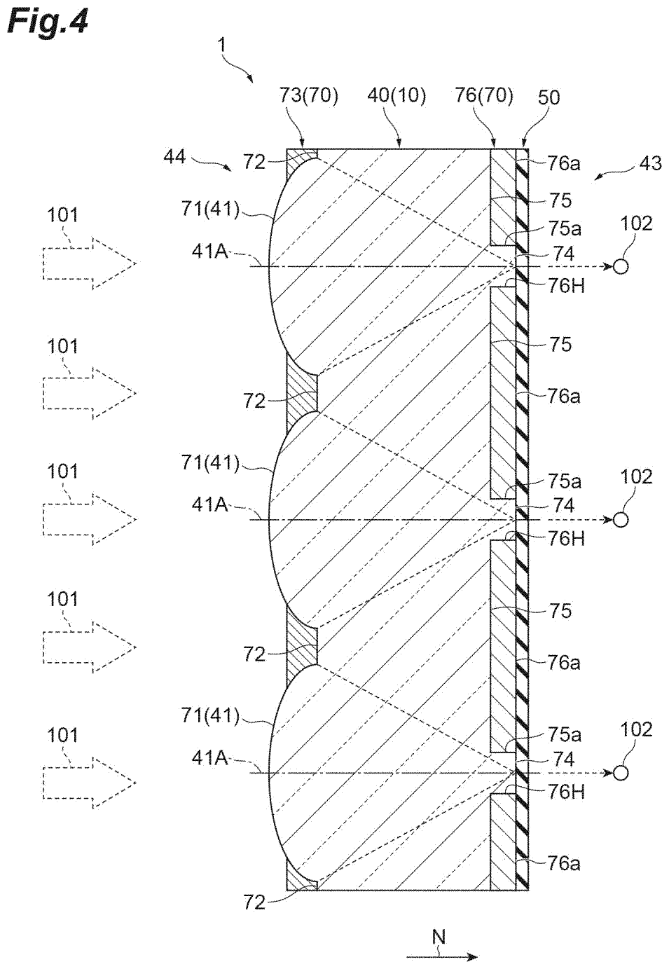

FIG. 3 is a cross-sectional view of the glass substrate 40. FIG. 4 is a cross-sectional view illustrating an enlarged main part of FIG. 3.

As illustrated in FIG. 4, the substrate back surface 44 includes a region that transmits the laser light 101 and a region that attenuates the laser light 101. The substrate back surface 44 includes a lens surface 71 and a back surface-side light shielding surface 72 (first region). The lens surface 71 is a surface of each of the microlenses 41. The back surface-side light shielding surface 72 is a portion interposed between lens surfaces 71. The region that transmits the laser light 101 is the lens surface 71. The region that attenuates the laser light 101 is the back surface-side light shielding surface 72. The back surface-side light shielding layer 73 (first light shielding layer) is provided on the back surface-side light shielding surface 72. The back surface-side light shielding layer 73 is opaque with respect to the laser light 101. The back surface-side light shielding layer 73 attenuates the laser light 101. The back surface-side light shielding layer 73 is made of, for example, chromium (Cr), aluminum (Al), or gold (Au), etc. When the back surface-side light shielding layer 73 is viewed in a plan view, it appears that a plurality of circular opening is provided in the back surface-side light shielding layer 73. The microlenses 41 are exposed from the openings. More specifically, the lens surface 71 is exposed from a circular opening provided in the back surface-side light shielding layer 73. On the substrate back surface 44, the laser light 101 enters the inside of the glass substrate 40 only through the lens surface 71. The back surface-side light shielding layer 73 comes into contact with the base 20. As a result, the back surface-side light shielding layer 73 is electrically connected to the base 20. By setting the base 20 (potential supply portion) to a desired potential, for example, a ground potential, the back surface-side light shielding layer 73 becomes a ground potential.

The substrate main surface 43 includes a region that transmits the laser light 101 and a region that attenuates the laser light 101. The substrate main surface 43 includes a plurality of light emitting surfaces 74 (first main surface portions) and main surface-side light shielding surfaces 75 (second main surface portions or second regions) interposed between the light emitting surfaces 74. The region that transmits the laser light 101 is each of the light emitting surfaces 74. The light emitting surface 74 is a region including an optical axis 41A of each of the microlenses 41 at a substantially central portion. The optical axis 41A is at the center position of the lens surface 71. Therefore, the lens surface 71 is coaxial with the light emitting surface 74 with reference to the optical axis 41A. The light emitting surface 74 is for the condensed laser light 101. A size of the light emitting surface 74 is smaller than the lens surface 71. In other words, the area of the light emitting surface 74 in a plan view is smaller than the area of the lens surface 71 in a plan view. For example, it is assumed that the light emitting surface 74 is circular. According to this assumption, a diameter of the light emitting surface 74 is smaller than a diameter of the lens surface 71. When the light emitting surface 74 is viewed in a plan view, the light emitting surface 74 is included in the lens surface 71 in a substantially coaxial state.

The region that attenuates the laser light 101 is the main surface-side light shielding surface 75. The main surface-side light shielding layer 76 (second light shielding layer) is provided on the main surface-side light shielding surface 75. The main surface-side light shielding layer 76 and the back surface-side light shielding layer 73 are included in a light shielding portion 70. The main surface-side light shielding surface 75 is provided at least in a portion facing the back surface-side light shielding surface 72. The main surface-side light shielding layer 76 is opaque with respect to the condensed laser light 101. The main surface-side light shielding layer 76 attenuates the condensed laser light 101. The main surface-side light shielding layer 76 is made of, for example, chromium (Cr), aluminum (Al), or gold (Au), etc. When the main surface-side light shielding layer 76 is viewed in a plan view, it appears that a plurality of circular light passing openings 76H is provided in the main surface-side light shielding layer 76. A diameter of each of the light passing openings 76H is smaller than a diameter of the microlens 41. At least in a region of the lens array 41S, the area of the main surface-side light shielding layer 76 is larger than the area of the back surface-side light shielding layer 73. The light emitting surface 74 is exposed from the light passing openings 76H. More specifically, the light emitting surface 74 is exposed from the circular light passing openings 76H provided in the main surface-side light shielding layer 76. On the substrate main surface 43, the laser light 101 is emitted to the outside of the glass substrate 40 only from the light emitting surface 74.

As illustrated in the cross-sectional view of FIG. 4, the main surface-side light shielding surface 75 and the light emitting surface 74 are not flush with each other. A step 75a is present between the main surface-side light shielding surface 75 and the light emitting surface 74. For example, a thickness from the substrate back surface 44 to the main surface-side light shielding surface 75 is less than a thickness from the substrate back surface 44 to the light emitting surface 74. The main surface-side light shielding surface 75 is recessed with respect to the light emitting surface 74. That is, the main surface-side light shielding surface 75 has a concave shape. The main surface-side light shielding layer 76 is provided to fill a concave portion.

The step 75a between the main surface-side light shielding surface 75 and the light emitting surface 74 is equal to a thickness of the main surface-side light shielding layer 76. A surface 76a of the main surface-side light shielding layer 76 is flush with the light emitting surface 74. The photoelectric surface 50 is provided on the surface 76a of the main surface-side light shielding layer 76 and the light emitting surface 74. The photoelectric surface 50 is provided on a flat surface substantially not having unevenness.

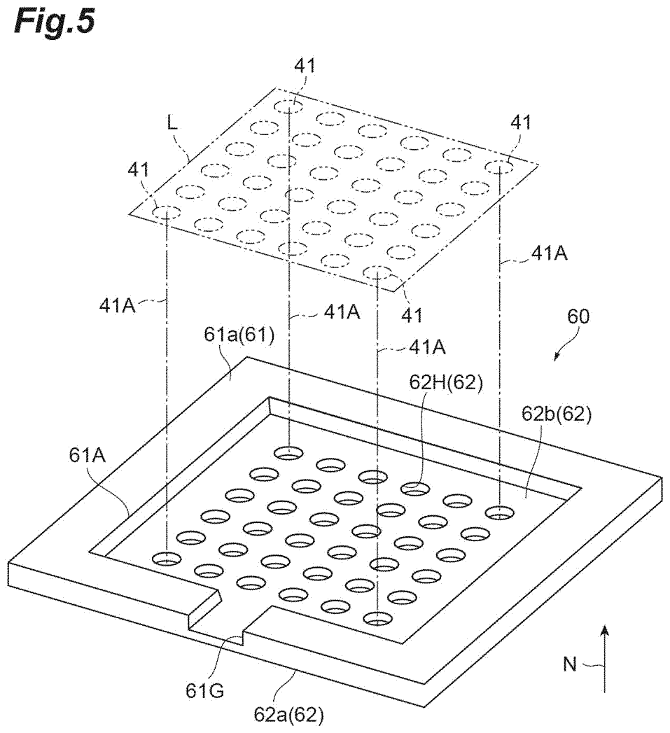

As illustrated in FIG. 5, the extraction electrode 60 has a substantially rectangular plate shape in the plan view in the direction facing the substrate main surface 43 of the glass substrate 40. The extraction electrode 60 is fixed to the substrate main surface 43. Specifically, the extraction electrode 60 is fixed to the electrode junction portion 45 by being bonded to the electrode junction portion 45 of the substrate main surface 43. An external shape of the extraction electrode 60 is substantially the same as an external shape of the electrode junction portion 45. The extraction electrode 60 has a frame portion 61 and an electrode portion 62. The frame portion 61 and the electrode portion 62 are an integrated member.

The frame portion 61 has a frame shape in the plan view in the direction facing the substrate main surface 43 of the glass substrate 40. The frame portion 61 surrounds at least the photoelectric surface 50. The frame portion 61 has a frame junction portion 61a. The frame junction portion 61a is bonded to the electrode junction portion 45. A planar shape of the frame junction portion 61a is substantially the same as a planar shape of the electrode junction portion 45. The frame portion 61 has an opening portion 61G. The electrode portion 62 is provided on the side of the frame portion 61 facing the frame junction portion 61a. The frame portion 61 extends along a normal direction N of the substrate main surface 43. The frame portion 61 has a predetermined height 61H (see FIG. 3). The frame portion 61 is the greatest factor that defines a distance in the normal direction N from the photoelectric surface 50 to the electrode portion 62. The height 61H of the frame portion 61 is the most significant factor that defines the distance from the photoelectric surface 50 to the electrode portion 62.

The electrode portion 62 covers a region surrounded by the frame portion 61. A predetermined voltage is applied to the electrode portion 62. An electric field is generated between the electrode portion 62 and the photoelectric surface 50 by the applied voltage. As a result, a photoelectron 102 generated on the photoelectric surface 50 is extracted. The electrode portion 62 has an electrode back surface 62b, an electrode main surface 62a, and an electrode hole 62H. The electrode back surface 62b faces the substrate main surface 43. The electrode back surface 62b faces the photoelectric surface 50. The electrode main surface 62a faces the electrode back surface 62b.

A plurality of electrode holes 62H is provided in the electrode portion 62. The electrode holes 62H are through-holes. The electrode holes 62H penetrate the electrode portion 62 from the electrode back surface 62b to the electrode main surface 62a. The electrode holes 62H are disposed, for example, in a plurality of rows and columns. The electrode holes 62H are regularly disposed. A region in which the electrode holes 62H are provided overlaps a region in which the lens array region L is formed. The region in which the electrode holes 62H are provided overlaps a region in which the photoelectric surface 50 is formed. The region in which the electrode holes 62H are provided overlaps a partial region of the photoelectric surface 50. The partial region of the photoelectric surface 50 is irradiated with the laser light 101 condensed by the lens array region L.

One electrode hole 62H corresponds to one microlens 41 in the lens array region L of the glass substrate 40. It is more preferable that a central axis of the electrode hole 62H coincides with the optical axis 41A of the predetermined microlens 41 facing the electrode hole 62H. In other words, it is more preferable that the central axis of the electrode hole 62H coincides with the optical axis 41A at a condensed spot by the microlens 41.

An alignment mark 62M (see FIG. 1) is provided on the electrode main surface 62a. The alignment mark 62M is used in bonding to the glass substrate 40. The alignment mark 62M is provided outside the region in which the electrode holes 62H are formed.

### Base

With reference to FIG. 1, the base 20 has a base main surface 20a and a base back surface 20b. The base 20 has a base hole 20H. The base hole 20H penetrates the base 20 from the base main surface 20a to the base back surface 20b. The base hole 20H guides the laser light 101 irradiated from the base back surface 20b side to the base main surface 20a side. The photoelectric surface electron source unit 10 is disposed on the base main surface 20a side. The laser light 101 guided to the base main surface 20a side enters the photoelectric surface electron source unit 10.

A unit arrangement portion 21, a fixing member arrangement portion 22, and a fastener exposure portion 23 are provided on the base main surface 20a. The photoelectric surface electron source unit 10 is disposed in the unit arrangement portion 21. The unit arrangement portion 21 is a concave. The unit arrangement portion 21 has a shape slightly larger than the glass substrate 40. The unit arrangement portion 21 has the base hole 20H. The fixing member arrangement portion 22 is a concave groove. The fixing member arrangement portion 22 extends from a corner to an outer peripheral edge of the unit arrangement portion 21. The fastener exposure portion 23 is a concave groove. The fastener exposure portion 23 extends from a side to the outer peripheral edge of the unit arrangement portion 21.

### Effect

The photoelectric surface electron source 1 includes the plurality of microlenses 41. Therefore, a plurality of photoelectrons 102 can be emitted by irradiation with the laser light 101. The photoelectric surface electron source 1 includes the light shielding portion 70. The light shielding portion 70 has the back surface-side light shielding layer 73 provided on the substrate back surface 44 and the main surface-side light shielding layer 76 provided on the substrate main surface 43. The back surface-side light shielding layer 73 can limit the laser light 101 incident on the glass substrate 40 to the microlenses 41. The main surface-side light shielding layer 76 can limit the laser light 101 irradiating the photoelectric surface 50 to the laser light 101 passing through the microlenses 41. As a result, light not passing through the microlenses 41 is inhibited from entering the photoelectric surface 50. The laser light 101 condensed by the microlenses 41 can be made incident on a desired region of the photoelectric surface 50 without fail. Therefore, it is possible to apply the electron beam with high accuracy. The back surface-side light shielding layer 73 and the main surface-side light shielding layer 76 reduce a possibility that a component passing through the photoelectric surface electron source 1 will be generated without being converted into photoelectrons by the photoelectric surface 50 in the laser light 101 irradiating the photoelectric surface electron source 1. As a result, it is possible to inhibit incident light from affecting an object to be processed, etc. due to the laser light 101 entering a device using the photoelectric surface electron source 1. The main surface-side light shielding layer 76 can inhibit stray light, which originates from the laser light 101 entering the microlens 41 from an unintended direction, from entering the photoelectric surface 50. The main surface-side light shielding layer 76 can inhibit stray light, which originates from multiple reflected light inside the glass substrate 40, from entering the photoelectric surface 50.

The light shielding portion 70 has the back surface-side light shielding layer 73 and the main surface-side light shielding layer 76. According to this configuration, a region of the substrate back surface 44 receiving the laser light 101 can be reliably limited only to the microlenses 41. Only the laser light 101 passing through the microlenses 41 on the substrate main surface 43 can be irradiated to the photoelectric surface 50.

The main surface-side light shielding layer 76 has the light passing openings 76H allowing the laser light 101 condensed by the microlenses 41 to pass therethrough. The area of the light passing openings 76H is smaller than the area of the microlenses 41. According to this configuration, it is possible to reliably irradiate the photoelectric surface 50 with only the laser light 101 condensed by the microlenses 41 on the substrate main surface 43.

The surface 76a of the main surface-side light shielding layer 76 is flush with the light emitting surface 74. According to such a configuration, the photoelectric surface 50 can be formed on the light emitting surface 74. Further, the photoelectric surface 50 can be formed on the main surface-side light shielding layer 76 flush with the light emitting surface 74. As a result, a surface of the photoelectric surface 50 is flattened. Therefore, it is possible to suppress formation of an electrostatic lens that disturbs a trajectory of the photoelectrons 102. As a result, a desired electron trajectory can be realized, and thus an electron beam can be applied with high accuracy. In some cases, a structure for protecting the photoelectric surface 50 and improving sensitivity may be further provided on the photoelectric surface 50. In this case, the structure for protecting the photoelectric surface 50 and improving sensitivity can be provided on the same plane without any step.

The base 20 is electrically connected to the back surface-side light shielding layer 73. The back surface-side light shielding layer 73 may have a desired potential. According to this configuration, charging of the back surface-side light shielding layer 73 can be suppressed.

The photoelectric surface electron source of the invention is not limited to the above mode.

### First Modified Example

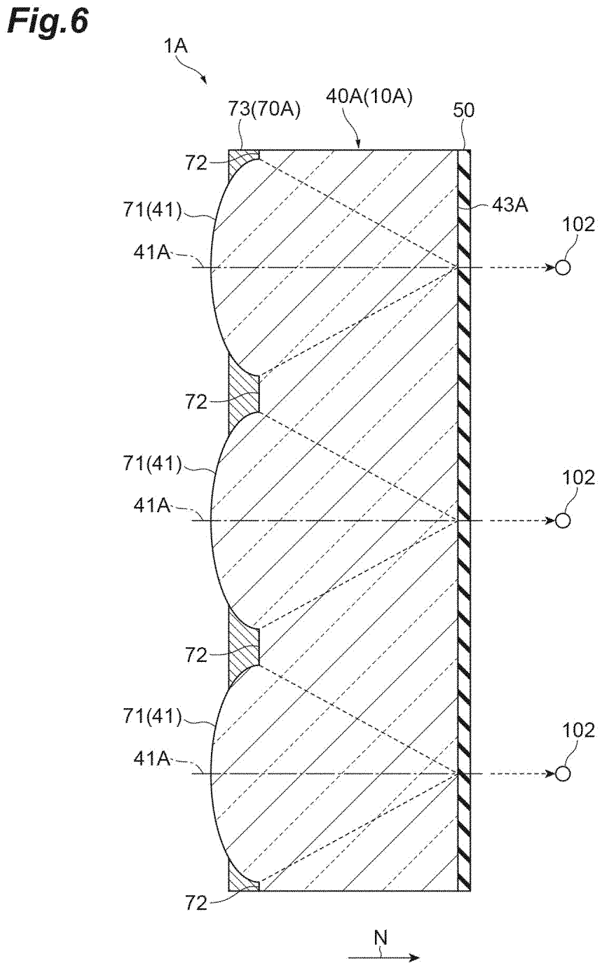

As illustrated in FIG. 6, a photoelectric surface electron source 1A of a first modified example has a photoelectric surface electron source unit 10A. The photoelectric surface electron source unit 10A has a glass substrate 40A, a back surface-side light shielding layer 73, and the photoelectric surface 50. The photoelectric surface electron source unit 10A has only the back surface-side light shielding layer 73 as the light shielding portion 70A. The photoelectric surface electron source unit 10A does not include the main surface-side light shielding layer 76. A substrate main surface 43A is a uniform plane. The substrate main surface 43A does not have a step similar to the substrate main surface 43 of the embodiment. The photoelectric surface 50 is provided on the substrate main surface 43A. According to this configuration, a region that receives the laser light 101 can be reliably limited to only the microlenses 41 by the back surface-side light shielding layer 73.

### Second Modified Example

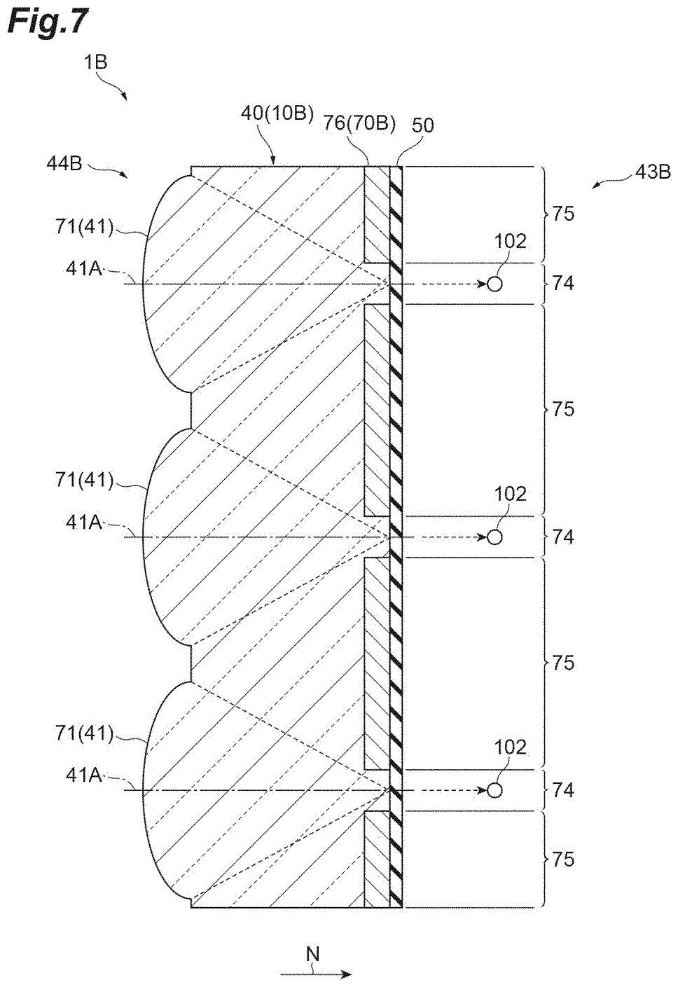

As illustrated in FIG. 7, a photoelectric surface electron source 1B of a second modified example has a photoelectric surface electron source unit 10B. The photoelectric surface electron source unit 10B has the glass substrate 40, the main surface-side light shielding layer 76, and the photoelectric surface 50. The photoelectric surface electron source unit 10B has only the main surface-side light shielding layer 76 as the light shielding portion 70B. The photoelectric surface electron source unit 10B does not include the back surface-side light shielding layer 73. Referring to a substrate back surface 44B, the entire back surface side of the glass substrate 40 is exposed. Therefore, incidence of the laser light 101 on the glass substrate 40 on the back surface side is not restricted. According to this configuration, on a substrate main surface 43B, only the laser light 101 passing through the microlenses 41 can be irradiated to the photoelectric surface 50.

### Third Modified Example

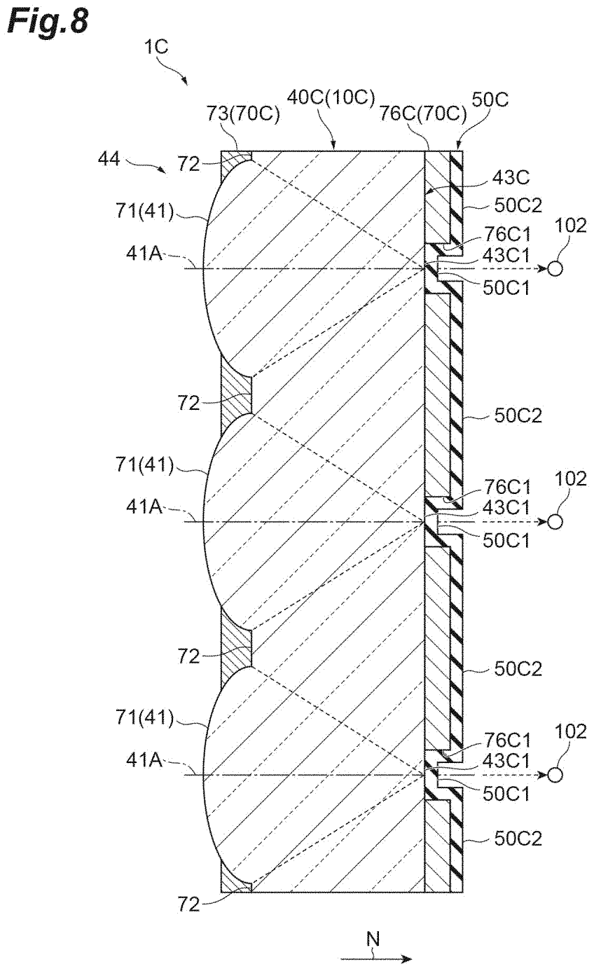

As illustrated in FIG. 8, a photoelectric surface electron source 1C of a third modified example has a photoelectric surface electron source unit 10C. The photoelectric surface electron source unit 10C has a glass substrate 40C, the back surface-side light shielding layer 73, a main surface-side light shielding layer 76C, and a photoelectric surface 50C. A configuration of the photoelectric surface electron source 1C of the third modified example on the back surface side is similar to that of the photoelectric surface electron source unit 10 of the embodiment. On the other hand, a configuration of the photoelectric surface electron source 1C of the third modified example on the main surface side is different from a configuration of the photoelectric surface electron source unit 10 of the embodiment on the main surface side.

The glass substrate 40C has a substrate main surface 43C. The substrate main surface 43C is substantially flat. The main surface-side light shielding layer 76C is provided on the substrate main surface 43C. The light shielding portion 70C has the back surface-side light shielding layer 73 and the main surface-side light shielding layer 76C. The main surface-side light shielding layer 76C is not embedded in a concave provided on the glass substrate similar to the main surface-side light shielding layer 76 of the embodiment. The main surface-side light shielding layer 76C has a circular light passing opening 76C1. The light passing opening 76C1 is coaxial with the optical axis 41A. A substrate exposure portion 43C1 is exposed from the light passing opening 76C1. The substrate exposure portion 43C1 is a part of the substrate main surface 43C. The photoelectric surface 50C is provided on a surface of the main surface-side light shielding layer 76C, an inner wall surface of the main surface-side light shielding layer 76C surrounding the light passing opening 76C1, and the substrate exposure portion 43C1. A portion of the photoelectric surface 50C provided in the substrate exposure portion 43C1 of the substrate main surface 43C is a first photoelectric surface portion 50C1. A portion of the photoelectric surface 50C provided on a surface of the main surface-side light shielding layer 76C is a second photoelectric surface portion 50C2. It is assumed that a thickness of the photoelectric surface 50C is constant regardless of location. According to this assumption, the second photoelectric surface portion 50C2 provided in the light passing opening 76C1 is recessed with respect to the first photoelectric surface portion 50C1 provided on the surface of the main surface-side light shielding layer 76C.

The main surface-side light shielding layer 76C has the light passing opening 76C1. The light passing opening 76C1 allows the laser light 101 condensed by the microlenses 41 to pass therethrough. The main surface-side light shielding layer 76C is directly formed on the substrate main surface 43C. The photoelectric surface 50C includes the first photoelectric surface portion 50C1 and the second photoelectric surface portion 50C2. The first photoelectric surface portion 50C1 is formed in the substrate exposure portion 43C1 exposed from the light passing opening 76C1. The second photoelectric surface portion 50C2 is formed in the main surface-side light shielding layer 76C. According to such a configuration, the laser light 101 condensed by the microlenses 41 can be reliably made incident on a desired region (the first photoelectric surface portion 50C1) of the photoelectric surface 50C. Therefore, it is possible to apply an electron beam with high accuracy.

### Fourth Modified Example

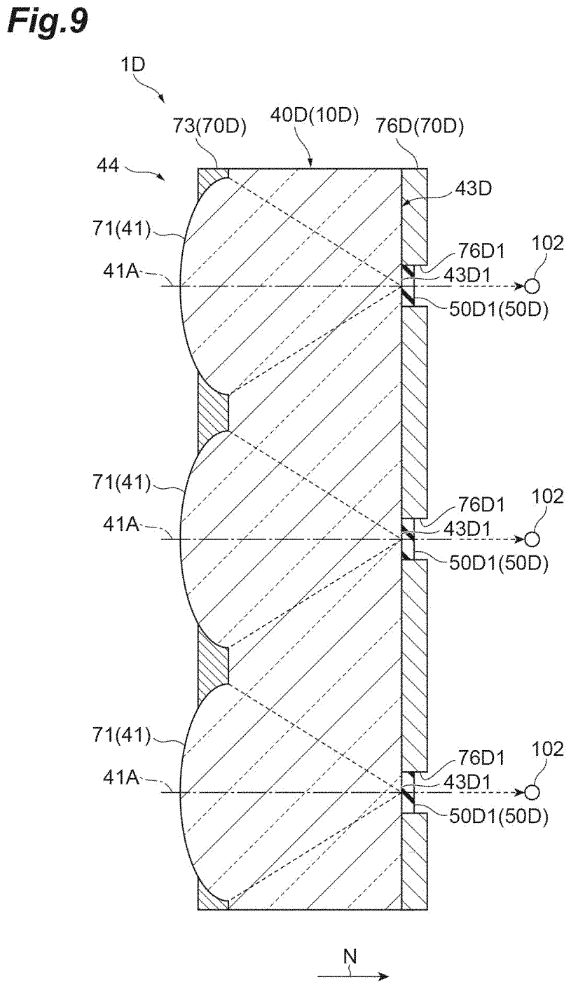

As illustrated in FIG. 9, a photoelectric surface electron source 1D of a fourth modified example has a photoelectric surface electron source unit 10D. The photoelectric surface electron source unit 10D has a glass substrate 40D, the back surface-side light shielding layer 73, a main surface-side light shielding layer 76D, and a photoelectric surface 50D. A configuration of the photoelectric surface electron source 1D of the fourth modified example on the back surface side is the same as the configuration of the photoelectric surface electron source unit 10 of the embodiment on the back surface side. On the other hand, a configuration of the photoelectric surface electron source 1D of the fourth modified example on the main surface side is different from the configuration of the photoelectric surface electron source unit 10 of the embodiment on the main surface side.

In the configuration of the fourth modified example, the configuration of the light shielding portion 70D is the same as the configuration of the light shielding portion 70C of the third modified example. A part of the photoelectric surface 50D corresponding to the second photoelectric surface portion is omitted. The photoelectric surface 50D has only the first photoelectric surface portion 50D1. The first photoelectric surface portion 50D1 is formed in a substrate exposure portion 43D1 exposed from a light passing opening 76D1. According to such a configuration, the laser light 101 condensed by the microlenses 41 can be reliably made incident on a desired region (first photoelectric surface portion 50D1) of the photoelectric surface 50D. Therefore, it is possible to apply an electron beam with high accuracy. The photoelectric surface 50D is provided only in a necessary region. As a result, even when there is stray light incident from a direction in which photoelectrons are emitted, there is a low possibility that the stray light will enter a region in which photoelectrons can be emitted. Therefore, it is possible to suppress unintended emission of the photoelectrons 102.

### REFERENCE SIGNS LIST

1, 1A, 1B, 1C, 1D: photoelectric surface electron source, 10, 10A, 10B, 10C, 10D: photoelectric surface electron source unit, 20: base, 20H: base hole, 21: unit arrangement portion, 22: fixing member arrangement portion, 23: fastener exposure portion, 40, 40A, 40C, 40D: glass substrate, 41: microlens (lens), 41S: lens array (lens part), 42: fixing member, 43: substrate main surface, 44: substrate back surface, 45: electrode junction portion, 45G: opening portion, 46: extraction power supply portion, 47: photoelectric surface power supply portion, 49A, 49B: conductive fastener, 50: photoelectric surface, 60: extraction electrode, 61: frame portion, 61G: opening portion, 61a: frame junction portion, 62: electrode portion, 62H: electrode hole, 70, 70A, 70B, 70C, 70D: light shielding portion, 71: lens surface, 72: back surface-side light shielding surface, 73: back surface-side light shielding layer (first region), 74: light emitting surface, 75: main surface-side light shielding surface, 76: main surface-side light shielding layer (second region), 101: laser light, 102: photoelectron, N: normal direction.

1. A photoelectric surface electron source comprising:
a substrate configured to receive light incident from a substrate back surface to emit the light from a substrate main surface on an opposite side from the substrate back surface;
a photoelectric surface provided on the substrate main surface and configured to receive the light and emit a photoelectron;
a lens part disposed on a side of the substrate back surface and including a plurality of lenses for condensing the light toward the photoelectric surface; and
a light shielding portion provided on the substrate,
wherein the light shielding portion has at least one of a first light shielding layer provided in a first region interposed between the plurality of lenses on the substrate back surface and a second light shielding layer provided in a second region facing the first region on the substrate main surface.

2. The photoelectric surface electron source according to claim 1, wherein the light shielding portion exclusively has the first light shielding layer.

3. The photoelectric surface electron source according to claim 1, wherein the light shielding portion exclusively has the second light shielding layer.

4. The photoelectric surface electron source according to claim 1, wherein the light shielding portion has the first light shielding layer and the second light shielding layer.

5. The photoelectric surface electron source according to claim 4, wherein:
the second light shielding layer has light passing openings allowing the light condensed by the lenses to pass therethrough; and
an area of the light passing openings is smaller than an area of the lenses.

6. The photoelectric surface electron source according to claim 4, wherein:
the second light shielding layer has a light passing opening allowing the light condensed by the lenses to pass therethrough and is directly formed on the substrate main surface; and
the photoelectric surface includes a first photoelectric surface portion formed on the substrate main surface exposed from the light passing opening, and a second photoelectric surface portion formed on the second light shielding layer.

7. The photoelectric surface electron source according to claim 6, wherein:
the substrate main surface includes a first main surface portion and a second main surface portion recessed from the first main surface portion; and
the second light shielding layer is provided on the second main surface portion.

8. The photoelectric surface electron source according to claim 7, wherein the second light shielding layer is flush with the first main surface portion.

9. The photoelectric surface electron source according to claim 1, further comprising a potential supply portion electrically connected to the first light shielding layer and used to set the first light shielding layer to a desired potential.
